(19) United States
(12) Patent Application Publication
(10) Pub. No.: US 2026/0080133 A1
(43) Pub. Date: Mar. 19, 2026

(54) A SYSTEM AND METHOD FOR DETERMINING DESIGN PARAMETERS FOR MARITIME INFRASTRUCTURE

(71) Applicant: RAMOT AT TEL-AVIV UNIVERSITY LTD., Tel Aviv (IL)

(72) Inventors: Rotem SOFFER, Tel Aviv (IL); Eliezer KIT, Tel Aviv (IL); Yaron TOLEDO, Tel Aviv (IL)

(21) Appl. No.: 19/110,445

(22) PCT Filed: Sep. 5, 2023
(86) PCT No.: PCT/IL2023/050949

§ 371 Date: Mar. 12, 2025

Related U.S. Application Data
(60) Provisional application No. 63/375,388, filed on Sep. 13, 2022.

(51) Int. Cl. G06F 30/28; G01C 13/00

(52) U.S. Cl. CPC G06F 30/28; G01C 13/00

(57) ABSTRACT

The presently disclosed subject matter aims to a system and method including a processing circuitry configured to: obtain: (a) a plurality of independent wave measurements of a body of a fluid, obtained over a period of time, wherein each independent wave measurement is acquired at a distinct location of the body of fluid; and (b) a respective ambient shearing current profile, wherein the respective ambient shearing current profile is based on ambient current values and directions, at different locations within the body of the fluid, related to the respective distinct location; based on the wave measurements and ambient shearing currents profile, assess wave directional spectra characterizing flow regime of waves of the body of fluid, while accounting for the effects of the ambient shearing currents during the wave measurements' period of time; and determine, based on the assessed wave directional spectra, one or more design parameters of the maritime infrastructure.

### TECHNICAL FIELD

The present invention relates to the field of determining design parameters for maritime infrastructure.

### BACKGROUND

Wave direction is a key parameter in characterizing a wave field, which has various implications for maritime infrastructure design (e.g., breakwaters, port entrances, reclamation, desalination plant in-lets, offshore platforms, etc.). At present, the customary approach for acquiring wave direction is by assessing directional wave spectra according to the wave potential theory.

The wave potential theory is a linearized description of the propagation of gravity waves on the surface of a homogeneous fluid layer. The basic assumption on which this theory rests is that the flow of the fluid is irrotational, hence the waves are limited to propagate only in a media of uniformly distributed in depth currents.

Despite its widespread use and acceptance for many years in extensive circles in the field of wave direction, the wave potential theory fails to consider the influence of ambient shearing currents, as the inherent assumption of this theory is that the ambient currents profile is either constant at depth, or more commonly, no existent. As a result, this theory cannot be appropriate for directional wave spectra calculations in the presence of shearing currents.

Thus, there is a need in the art for a new system and method for determining design parameters for maritime infrastructure.

### GENERAL DESCRIPTION

In accordance with a first aspect of the presently disclosed subject matter, there is provided an interpretation method for determining placement parameters for maritime infrastructure comprising: obtaining: (a) a plurality of independent wave measurements of a body of a fluid, obtained over a period of time, wherein each independent wave measurement is acquired at a distinct location of the body of fluid, by a respective sensor; and (b) a respective ambient shearing current profile, wherein the respective ambient shearing current profile is based on ambient current values and directions at different locations within the body of the fluid, related to the respective distinct location; based on the wave measurements and the ambient shearing currents profile, assessing wave directional spectra characterizing flow regime of waves of the body of fluid, while accounting for the effects of the ambient shearing currents during the wave measurements' period of time; and determining, based on the assessed wave directional spectra, one or more design parameters of the maritime infrastructure.

In some cases, design parameters are utilized to determine placement of the maritime infrastructure.

In some cases, design parameters are utilized for maritime assessment.

In some cases, the maritime assessment is one of: a beach morphology design, an environmental impact, cliff erosion assessments and predictions, a climate change impact study, a forecast physical modeling, a hind-cast physical modeling, a forecast numerical modeling, or a hind-cast numerical modeling.

In some cases, the wave measurements involve measurements of particles of any kind found within the body of fluid.

In some cases, the wave measurements are measured directly.

In some cases, the directly measured wave measurements are one of: temporal measurements or spatial measurements.

In some cases, the wave measurements are measured indirectly.

In some cases, the indirectly measured wave measurements are one of: physical, geometrical, or chemical measurements.

In some cases, the wave measurements are sea elevation measurements.

In some cases, (a) the distinct location is a location found within the body of fluid, and (b) the wave measurements are measurements of fluid of the body of fluid.

In some cases, (a) the distinct location is a location found above the body of fluid, and (b) the wave measurements are measurements of fluid found above the body of water.

In some cases, the fluid is one of: wind or air.

In some cases, the sensor is a single sensor or a measurement instrument including a plurality of sensors.

In some cases, the single sensor or the measurement instrument is one of: one or more ADCPs (Acoustic Doppler Current Profiler), one or more wave buoys, one or more wave drifters, one or more pressure gauges, one or more wave staff, one or more current meters, one or more current profilers, one or more tilt meters, one or more acceleration meters, one or more compasses, compasses sea images, compasses PTVs (particle tracking velocimetry), compasses PIVs (particle image velocimetry), compasses thermometers, one or more LIDARs (Light Detection and Ranging), one or more Radars, one or more sonars, one or more turbidity sensors, one or more mooring risers, one or more shadow graphs, one or more hot wires and films, one or more strain-gauges, one or more sonic winds, or a combination thereof.

In some cases, the sensor is placed either at the distinct location or at a location remote from the distinct location.

In some cases, the different locations are depth points between the bottom of the body of fluid and the fluid's surface along a water column.

In some cases, the respective ambient shearing currents profile is either measured or assumed.

In some cases, the ambient shearing currents profile is obtained using an Acoustic Doppler Current Profiler (ACDP).

In some cases, the flow regime of waves includes either waves found on the fluid surface, internal waves found within the body of the fluid, or a combination thereof.

In some cases, the wave directional spectra is power density spectra (PDS).

In some cases, the wave directional spectra is wave amplitude spectra (PDS).

In some cases, the wave directional spectra is a one-dimension spectra, derived from the wave directional spectra.

In some cases, the wave directional spectra includes spatial wave growth and decay coefficients.

In some cases, the assessment of the wave directional spectra is performed by calculating transfer functions, while accounting for the ambient shearing currents profile.

In some cases, the maritime infrastructure is one of: a ship, a rig, a breakwater, an offshore wind structure, a subsea pipeline, a quay wall, ports, jetties, quays, wharfs, land reclamations, a desalination plant, artificial islands, marine intakes and outlets, marine agriculture infrastructure.

In some cases, the shearing currents profile is an average of horizontal shearing currents during the period of time.

In accordance with a second aspect of the presently disclosed subject matter, there is provided a system for determining design parameters for maritime infrastructure, the system comprising a processing circuitry configured to: obtain: (a) a plurality of independent wave measurements of a body of a fluid, obtained over a period of time, wherein each independent wave measurement is acquired at a distinct location of the body of fluid, by a respective sensor; and (b) a respective ambient shearing current profile, wherein the respective ambient shearing current profile is based on ambient current values and directions, at different locations within the body of the fluid, related to the respective distinct location; based on the wave measurements and the ambient shearing currents profile, assess wave directional spectra characterizing flow regime of waves of the body of fluid, while accounting for the effects of the ambient shearing currents during the wave measurements' period of time; and determine, based on the assessed wave directional spectra, one or more design parameters of the maritime infrastructure.

In some cases, design parameters are utilized to determine placement of the maritime infrastructure.

In some cases, design parameters are utilized for maritime assessment.

In some cases, the maritime assessment is one of: a beach morphology design, an environmental impact, cliff erosion assessments and predictions, a climate change impact study, a forecast physical modeling, a hind-cast physical modeling, a forecast numerical modeling, or a hind-cast numerical modeling.

In some cases, the wave measurements involve measurements of particles of any kind found within the body of fluid.

In some cases, the wave measurements are measured directly.

In some cases, the directly measured wave measurements are one of: temporal measurements or spatial measurements.

In some cases, the wave measurements are measured indirectly.

In some cases, the indirectly measured wave measurements are one of: physical, geometrical, or chemical measurements.

In some cases, the wave measurements are sea elevation measurements.

In some cases, (a) the distinct location is a location found within the body of fluid, and (b) the wave measurements are measurements of fluid of the body of fluid.

In some cases, (a) the distinct location is a location found above the body of fluid, and (b) the wave measurements are measurements of fluid found above the body of water.

In some cases, the fluid is one of: wind or air.

In some cases, the sensor is a single sensor or a measurement instrument including a plurality of sensors.

In some cases, the single sensor or the measurement instrument is one of: one or more ADCPs (Acoustic Doppler Current Profiler), one or more wave buoys, one or more wave drifters, one or more pressure gauges, one or more wave staff, one or more current meters, one or more current profilers, one or more tilt meters, one or more acceleration meters, one or more compasses, compasses sea images, compasses PTVs (particle tracking velocimetry), compasses PIVs (particle image velocimetry), compasses thermometers, one or more LIDARs (Light Detection and Ranging), one or more Radars, one or more sonars, one or more turbidity sensors, one or more mooring risers, one or more shadow graphs, one or more hot wires and films, one or more strain-gauges, one or more sonic winds, or a combination thereof.

In some cases, the sensor is placed either at the distinct location or at a location remote from the distinct location.

In some cases, the different locations are depth points between the bottom of the body of fluid and the fluid's surface along a water column.

In some cases, the respective ambient shearing currents profile is either measured or assumed.

In some cases, the ambient shearing currents profile is obtained using an Acoustic Doppler Current Profiler (ACDP).

In some cases, the flow regime of waves includes either waves found on the fluid surface, internal waves found within the body of the fluid, or a combination thereof.

In some cases, the wave directional spectra is power density spectra (PDS).

In some cases, the wave directional spectra is wave amplitude spectra (PDS).

In some cases, the wave directional spectra is a one-dimension spectra, derived from the wave directional spectra.

In some cases, the wave directional spectra includes spatial wave growth and decay coefficients.

In some cases, the assessment of the wave directional spectra is performed by calculating transfer functions, while accounting for the ambient shearing currents profile.

In some cases, the maritime infrastructure is one of: a ship, a rig, a breakwater, an offshore wind structure, a subsea pipeline, a quay wall, ports, jetties, quays, wharfs, land reclamations, a desalination plant, artificial islands, marine intakes and outlets, marine agriculture infrastructure.

In some cases, the shearing currents profile is an average of horizontal shearing currents during the period of time.

In accordance with a second aspect of the presently disclosed subject matter, there is provided a non-transitory computer readable storage medium having computer readable program code embodied therewith, the computer readable program code, executable by at least one processor to perform an interpretation method for determining placement parameters for maritime infrastructure, the method comprising: obtaining: (a) a plurality of independent wave measurements of a body of a fluid, obtained over a period of time, wherein each independent wave measurement is acquired at a distinct location of the body of fluid, by a respective sensor; and (b) a respective ambient shearing current profile, wherein the respective ambient shearing current profile is based on ambient current values and directions at different locations within the body of the fluid, related to the respective distinct location; based on the wave measurements and the ambient shearing currents profile, assessing wave directional spectra characterizing flow regime of waves of the body of fluid, while accounting for the effects of the ambient shearing currents during the wave measurements' period of time; and determining, based on the assessed wave directional spectra, one or more design parameters of the maritime infrastructure.

### BRIEF DESCRIPTION OF THE DRAWINGS

In order to understand the presently disclosed subject matter and to see how it may be carried out in practice, the subject matter will now be described, by way of non-limiting examples only, with reference to the accompanying drawings, in which:

FIG. 1 is a graph illustrating Longuet-Higgins-Mitsuyasu spread function G(θ), in accordance with the presently disclosed subject matter;

FIG. 2 is an illustration of an exemplary zero order current velocity profile U⁽⁰⁾(z), in accordance with the presently disclosed subject matter;

FIG. 3 is an illustration of single frequency wave input for Longuet-Higgins-Mitsuyasu spread, in accordance with the presently disclosed subject matter;

FIG. 4 is a graph illustrating the Power Density Spectrum (PDS) of the single frequency wave input as processed, in accordance with the presently disclosed subject matter;

FIG. 5 is a graph illustrating processed spread functions G(f, θ) of the single frequency wave for Longuet-Higgins-Mitsuyasu spread, in accordance with the presently disclosed subject matter;

FIGS. 6A-6C are graphs illustrating the 2D Cᵢ coefficients solved from the Rayleigh Boundary Value Problem (BVP) per frequency and direction and their distribution for the single frequency wave, in accordance with the presently disclosed subject matter;

FIG. 7 is a graph illustrating the wave number k, solved from Rayleigh BVP, indicating dispersion relation, and the obtained transfer functions Hᵤ and Hᵥ of the single frequency wave, in accordance with the presently disclosed subject matter;

FIG. 8 is a block diagram schematically illustrating one example of a system for determining design parameters for maritime infrastructure, in accordance with the presently disclosed subject matter;

FIG. 9 is a flowchart illustrating an example of a sequence of operations carried out by a system for determining design parameters for maritime infrastructure, in accordance with the presently disclosed subject matter;

FIG. 10 is an exemplary flowchart illustrating an example of a sequence of operations carried out by a system for determining design parameters for maritime infrastructure, in accordance with the presently disclosed subject matter;

FIG. 11 is a graph illustrating the averaged east and west horizontal velocities u⁽⁰⁾, v⁽⁰⁾, correspondingly, for January 27th, at 6:00, offshore Tel Aviv, at a depth of 16 meters;

FIGS. 12A-12B are representations of the dispersion relation k(f, θ) and the numerical transfer functions H_{L}(f, θ) accounting for the shearing current profile for January 27th, at 6:00, offshore Tel Aviv at a depth of 16 meters;

FIG. 13 is an illustration of the directional power density spectrum S(f,θ) calculated according to the new interpretation method of the presently disclosed subject matter, and according to the wave potential theory for the data collected on January 27th, at 6:00 a.m., offshore Tel Aviv, at a depth of 16 meters;

FIG. 14 is an illustration of the directional spread functions G(f, θ) calculated according to the new interpretation method of the presently disclosed subject matter, and according to the wave potential theory for the data collected on January 27th, at 6:00 a.m., offshore Tel Aviv, at a depth of 16 meters; and,

FIG. 15 is an illustration of the mean wave direction θm calculated according to the new interpretation method of the presently disclosed subject matter, and according to the wave potential theory for the data collected on January 27th, at 6:00 a.m., offshore Tel Aviv, at a depth of 16 meters.

### DETAILED DESCRIPTION

In the following detailed description, numerous specific details are set forth in order to provide a thorough understanding of the presently disclosed subject matter. However, it will be understood by those skilled in the art that the presently disclosed subject matter may be practiced without these specific details. In other instances, well-known methods, procedures, and components have not been described in detail so as not to obscure the presently disclosed subject matter.

In the drawings and descriptions set forth, identical reference numerals indicate those components that are common to different embodiments or configurations.

Unless specifically stated otherwise, as apparent from the following discussions, it is appreciated that throughout the specification discussions utilizing terms such as “obtaining”, “assessing”, “determining”, “calculating” or the like, include action and/or processes of a computer that manipulate and/or transform data into other data, said data represented as physical quantities, e.g., such as electronic quantities, and/or said data representing the physical objects. The terms “computer”, “processor”, “processing resource”, “processing circuitry”, and “controller” should be expansively construed to cover any kind of electronic device with data processing capabilities, including, by way of non-limiting example, a personal desktop/laptop computer, a server, a computing system, a communication device, a smartphone, a tablet computer, a smart television, a processor (e.g. digital signal processor (DSP), a microcontroller, a field programmable gate array (FPGA), an application specific integrated circuit (ASIC), etc.), a group of multiple physical machines sharing performance of various tasks, virtual servers co-residing on a single physical machine, any other electronic computing device, and/or any combination thereof.

The operations in accordance with the teachings herein may be performed by a computer specially constructed for the desired purposes or by a general-purpose computer specially configured for the desired purpose by a computer program stored in a non-transitory computer readable storage medium. The term “non-transitory” is used herein to exclude transitory, propagating signals, but to otherwise include any volatile or non-volatile computer memory technology suitable to the application.

As used herein, the phrase “for example,” “such as”, “for instance” and variants thereof describe non-limiting embodiments of the presently disclosed subject matter. Reference in the specification to “one case”, “some cases”, “other cases” or variants thereof means that a particular feature, structure or characteristic described in connection with the embodiment(s) is included in at least one embodiment of the presently disclosed subject matter. Thus, the appearance of the phrase “one case”, “some cases”, “other cases” or variants thereof does not necessarily refer to the same embodiment(s).

It is appreciated that, unless specifically stated otherwise, certain features of the presently disclosed subject matter, which are, for clarity, described in the context of separate embodiments, may also be provided in combination in a single embodiment. Conversely, various features of the presently disclosed subject matter, which are, for brevity, described in the context of a single embodiment, may also be provided separately or in any suitable sub-combination.

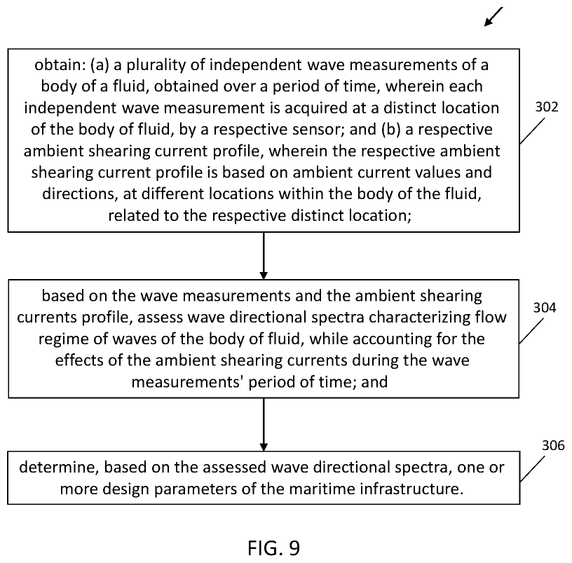

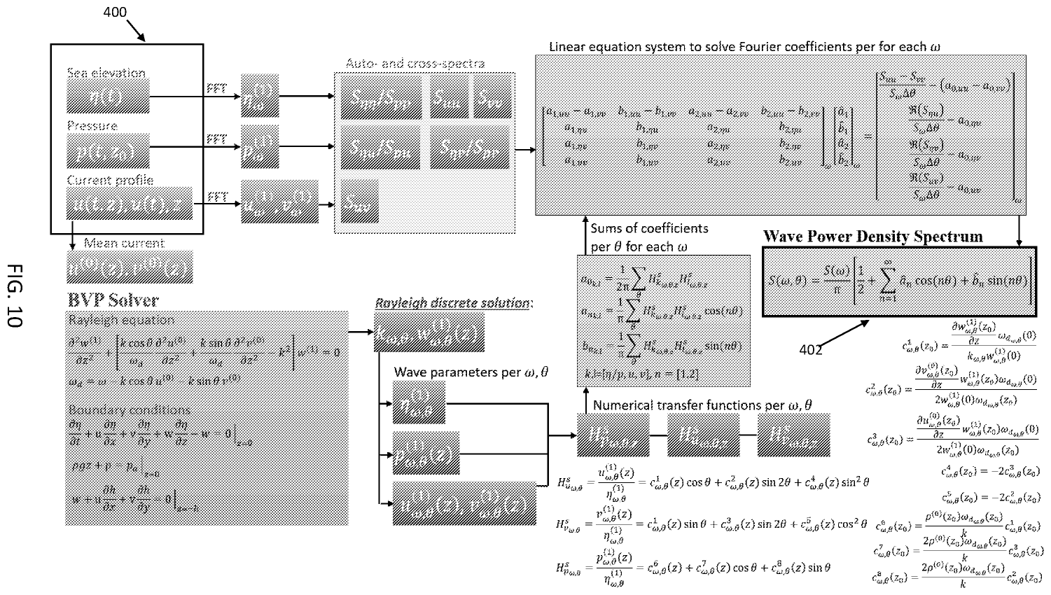

In embodiments of the presently disclosed subject matter, fewer, more and/or different stages than those shown in FIGS. 9 and 10 may be executed. In embodiments of the presently disclosed subject matter one or more stages illustrated in FIGS. 9 and 10 may be executed in a different order and/or one or more groups of stages may be executed simultaneously. Each module in FIG. 8 can be made up of any combination of software, hardware and/or firmware that performs the functions as defined and explained herein. The modules in FIG. 8 may be centralized in one location or dispersed over more than one location. In other embodiments of the presently disclosed subject matter, the system may comprise fewer, more, and/or different modules than those shown in FIG. 8.

Any reference in the specification to a method should be applied mutatis mutandis to a system capable of executing the method and should be applied mutatis mutandis to a non-transitory computer readable medium that stores instructions that once executed by a computer result in the execution of the method.

Any reference in the specification to a system should be applied mutatis mutandis to a method that may be executed by the system and should be applied mutatis mutandis to a non-transitory computer readable medium that stores instructions that may be executed by the system.

Any reference in the specification to a non-transitory computer readable medium should be applied mutatis mutandis to a system capable of executing the instructions stored in the non-transitory computer readable medium and should be applied mutatis mutandis to method that may be executed by a computer that reads the instructions stored in the non-transitory computer readable medium.

By way of introduction, the existing methods describing the directional spectrum derivation for a given point sensor are limited to the wave potential theory. This means that these methods may account for the effect of ambient currents only if these currents are constant and uniformly distributed along the water column. In reality, ambient shearing currents are rotational and change along the vertical axis (vertically shearing currents) and, as such, may significantly change wave properties and dispersion relation. Though ambient shearing currents and wave flow have been theoretically related for almost 50 years, the effect of ambient shearing currents has not been accounted for in any of the existing wave data processing methods of wave buoys, pressure gauges, and ADCPs. Instead, these currents were either assumed to be uniform or non-existent altogether.

In order to account for the effect of shearing currents, the potential approach, on the basis of which the existing methods rely, must be replaced with a non-potential approach accounting for the average shearing current profile. The presently disclosed subject matter aims to implement just that. Hereinafter are the basic assumption and derivation milestone s used to achieve this purpose:

Initially, a differential equations setup is acquired. The differential equations setup may include the Euler equations for momentum and mass conservation, and the state equation for incomprehensibility fluid (1)-(5):

$$\frac{\partial [ ρ u ]}{\partial t} + u \frac{\partial [ ρ u ]}{\partial x} + v \frac{\partial [ ρ u ]}{\partial y} + w \frac{\partial [ ρ u ]}{\partial z} = - \frac{\partial p}{\partial x} , \qquad ( 1 )$$

$$\frac{\partial [ ρ v ]}{\partial t} + u \frac{\partial [ ρ v ]}{\partial x} + v \frac{\partial [ ρ v ]}{\partial y} + w \frac{\partial [ ρ v ]}{\partial z} = - \frac{\partial p}{\partial y} , \qquad ( 2 )$$

$$\frac{\partial [ ρ w ]}{\partial t} + u \frac{\partial [ ρ w ]}{\partial x} + v \frac{\partial [ ρ w ]}{\partial y} + w \frac{\partial [ ρ w ]}{\partial z} + ρ g = - \frac{\partial p}{\partial z} , \qquad ( 3 )$$

$$\frac{\partial ρ}{\partial t} + \frac{\partial [ ρ u ]}{\partial x} + \frac{\partial [ ρ v ]}{\partial y} + \frac{\partial [ ρ w ]}{\partial z} = 0 , \qquad ( 4 )$$

$$\frac{\partial ρ}{\partial t} + u \frac{\partial ρ}{\partial x} + v \frac{\partial ρ}{\partial y} + w \frac{\partial ρ}{\partial z} = 0. \qquad ( 5 )$$

In these equations (i) u(x,y, z, t) and v(x, y, z, t) may be the horizontal current velocity in the x, y directions, respectively, (ii) w(x, y, z, t) may be the vertical current velocity, (iii) ρ(x, y, z, t) may be the fluid density, and (iv) p(x, y, z, t) may be the pressure.

It is to be noted that, in some cases, the perturbation approach may be used to analyze the equations setup.

Next, each variable may have (i) its zero order averaged component, denoted ξ⁽⁰⁾, related to the mean current flow, and (ii) its higher order fluctuating part, generated by the waves, denoted by \tilde{ξ}, so ξ=ξ⁽⁰⁾+\tilde{ξ}.

In cases involving higher order perturbations, the perturbations may be denoted by (6):

$$\tilde{ξ} ( x , y , z , t ) = [ ϵ {ξ}^{( 1 )} ( x , y , z , t ) + {ϵ}^{2} {ξ}^{( 2 )} ( x , y , z , t ) + … ] exp [ iS ( x , y , t ) ] , \qquad ( 6 )$$

where S(x, y, t) is the wave phasor.

It is to be noted (i) that higher orders of the perturbation may be negligible compared to the first order, and (ii) that each variable may be discussed in terms of the relative smallness of spatial and temporal variations, between the ambient current variability and the characteristic wave scale. The spatial variation smallness may compare the current variation to the wave length scaling, whereas the temporal variation smallness may be compared to the wave period. Both of these variations may be assumed to be of the same small order, and be denoted by E.

The perturbation solution accounting for the first order terms, employing the Boussinesq approximation, may yield the following Rayleigh equation (7):

$$\frac{{\partial }^{2} {w}^{( 1 )}}{\partial {z}^{2}} + [ \frac{k cos θ}{{ω}_{d}} \frac{{\partial }^{2} {u}^{( 0 )}}{\partial {z}^{2}} + \frac{k sin θ}{{ω}_{d}} \frac{{\partial }^{2} {v}^{( 0 )}}{\partial {z}^{2}} - \frac{{k}^{2} g}{{ρ}^{( 0 )} {ω}_{d}^{2}} \frac{\partial {ρ}^{( 0 )}}{\partial z} - {k}^{2} ] {w}^{( 1 )} \qquad ( 7 )$$

where ω_{d} may be the Doppler shifted frequency defined by (8):

$${ω}_{d} ( z ) = ω - k cos θ {u}^{( 0 )} ( z ) - k sin θ {v}^{( 0 )} ( z ) \qquad ( 8 )$$

For known horizontal current components u⁽⁰⁾(z), v⁽⁰⁾(z), and a known radial frequency ω in a given wave direction θ, the vertical current velocity oscillation w⁽¹⁾(z) and the corresponding wave number k may be found by solving the eigenvalue problem formulated in the Boundary Value Problem (BVP), based on Rayleigh equation (7). Substituting the kinematic surface boundary conditions (KSBC) in the dynamic surface boundary conditions (DSBC), may yield a combined surface boundary condition (9), which together., with non-porous bottom (BBC) may provide boundary conditions for the BVP.

$$\frac{\partial {w}^{( 1 )}}{\partial z} + [ \frac{k cos θ}{{ω}_{d}} \frac{\partial {u}^{( 0 )}}{\partial z} + \frac{k sin θ}{{ω}_{d}} \frac{\partial {v}^{( 0 )}}{\partial z} - \frac{{k}^{2} g}{{ω}_{d}^{2}} ] {w}^{( 1 )} {\vert}_{z = 0} = 0 \qquad ( 9 )$$

The non-porous bottom (BBC), under the assumption of mild-slope bathymetry, may yield the following boundary condition (10):

$${ω}^{( 1 )} {\vert}_{z = - h} = 0 \qquad ( 10 )$$

while a last boundary condition may be required to solve the Rayleigh equation, so that the surface vertical velocities may be normalized to one at η⁽⁰⁾, such that:

$${ω}^{( 1 )} {\vert}_{z = - h} = 1 \qquad ( 11 )$$

For constant fluid density, the Rayleigh equation (7) may be reduced to the Rayleigh equation given in (12):

$$\frac{{\partial }^{2} {ω}^{( 1 )}}{\partial {z}^{2}} + [ \frac{k cos θ}{{ω}_{d}} \frac{{\partial }^{2} {u}^{( 0 )}}{\partial {z}^{2}} + \frac{k sin θ}{{ω}_{d}} \frac{{\partial }^{2} {υ}^{( 0 )}}{\partial {z}^{2}} - {k}^{2} ] {ω}^{( 1 )} = 0 \qquad ( 12 )$$

It is to be noted that all the fluctuating parameters of the first order may be derived as a function of the oscillatory vertical velocity w((z), according to the initial equation setup.

$$\begin{matrix}{η}^{( 1 )} = \frac{i {ω}^{( 1 )} {\vert}_{z = 0}}{{ω}_{d}} , \\ \tilde{η} ( x , y , t ) = {η}^{( 1 )} {e}^{[ iS ( x , y , t ) ]} . \\ {u}^{( 1 )} = i \frac{\partial {ω}^{( 1 )}}{\partial z} \frac{cos θ}{k} + \\ \frac{i {ω}^{( 1 )}}{{ω}_{d}} [ \frac{\partial {u}^{( 0 )}}{\partial z} ( {cos}^{2} θ - 1 ) + \frac{\partial {v}^{( 0 )}}{\partial z} \cdot θ cos θ ] ,\end{matrix} \qquad ( 13 )$$

$$\begin{matrix}\tilde{u} ( x , y , z , t ) = {u}^{( 1 )} ( z ) {e}^{[ iS ( x , y , t ) ]} . \\ {υ}^{( 1 )} = i \frac{\partial {ω}^{( 1 )}}{\partial z} \frac{sin θ}{k} + \frac{i {ω}^{( 1 )}}{{ω}_{d}} [ \frac{\partial {υ}^{( 0 )}}{\partial z} ( {sin}^{2} θ - 1 ) + \frac{\partial {υ}^{( 0 )}}{\partial z} sin θ cos θ ] ,\end{matrix} \qquad ( 14 )$$

$$\begin{matrix}\tilde{υ} ( x , y , z , t ) = {υ}^{( 1 )} ( z ) {e}^{[ iS ( x , y , t ) ]} . \\ {p}^{( 1 )} = i \frac{\partial {ω}^{( 1 )}}{\partial z} \frac{{ω}_{d} {ρ}_{0}}{{k}^{2}} + \frac{i {ω}^{( 1 )} {ρ}^{( 0 )}}{k} [ \frac{\partial {u}^{( 0 )}}{\partial z} cos θ + \frac{\partial {υ}^{( 0 )}}{\partial z} sin θ ] ,\end{matrix} \qquad ( 15 )$$

$$\begin{matrix}\tilde{p} ( x , y , z , t ) = {p}^{( 1 )} ( z ) {e}^{[ iS ( x , y , t ) ]} . \\ {ρ}^{( 1 )} = \frac{i {ω}^{( 1 )} \frac{\partial {ρ}^{( 0 )}}{\partial z}}{{ω}_{d}} ,\end{matrix} \qquad ( 16 )$$

$$\tilde{ρ} ( x , y , z , t ) = {ρ}^{( 1 )} {e}^{[ iS ( x , y , t ) ]} . \qquad ( 17 )$$

$$S ( x , y , t ) = k cos θ x + k sin θ y - ω t + ϕ , \qquad ( 18 )$$

where φ may be a known wave phase, and for point measurement x and y, may be set to zero.

### Cross-Spectra Analysis

In cross-spectra analyses, the transfer functions are employed to relate the oscillatory velocities to the sea elevation. In potential theory, the transfer function Kc (co, k) relates oscillatory velocities to sea elevation by employing a simple circular projection on the x and y axes, according to cos θ, sin θ functions, correspondingly, whereas datasets of sea elevations and the orthogonal horizontal velocities are used for assessing the wave directional spread.

In accordance with the above, within the potential theory framework, horizontal velocities measured by an ADCP instrument are simply projected according to the Kc transfer function, on the x and y axes and their respective cos θ and sin θ functions. In addition, another inaccuracy of the potential data processing method is the calculation of k, according to the potential dispersion relation. Given that the potential method may be inaccurately employed when the flow terms are rotational, this method may account for the current velocity only for an ambient current profile uniformly distributed in depth or a zero current.

### Numerical Transfer Functions Derivation for Rotational Flows

According to the presently disclosed subject matter, the Rayleigh Boundary Value Problem (BVP) solution may produce more accurate relations between the wave oscillatory parameters. For example, in the case of an ADCP employing Acoustic Surface Tracking (AST) beam. The relations between the oscillatory velocities and the sea elevation given in new numerical transfer functions and obtained from the Rayleigh BVP solution in the presence of shearing currents, are more accurate compared to those obtained via potential theory. As said the Rayleigh BVP solution does not assume irrotationality of the flow. Based on this distinction, an example of the new methodology of data processing for calculating the directional Power Density Spectrum (PDS), based on the Rayleigh BVP, is introduced as follows:

Relations between the perturbated

$${η}_{ω , θ} , {u}_{ω , θ}^{( 1 )} ( z ) , {υ}_{ω , θ}^{( 1 )} ( z ) , {ω}_{ω , θ}^{( 1 )} ( z ) , and {p}_{ω , θ}^{( 1 )} ( z )$$

may be

$${H}_{{u}_{ω , θ}}^{s} ( z ) , and {H}_{{υ}_{ω , θ}}^{s} ( z )$$

established using the Rayleigh BVP. Since the Rayleigh equation setup for the general case of shearing currents has a numerical solution only, the new numerical relations between the sea elevation and the current oscillatory velocities coefficients in the frequency domain may be established according to the solution of the Rayleigh BVP (13), (14), (15), (16), including solutions' derivatives, and are denoted as transfer functions

$${H}_{{u}_{ω , θ}}^{s} ( z ) , and {H}_{{υ}_{ω , θ}}^{s} ( z ) ,$$

corresponding to the x, y axes, and transfer functions corresponding to the z axis, given as:

$${H}_{{υ}_{ω , θ}}^{s} ( z ) = \frac{{u}_{ω , θ}^{( 1 )} ( z )}{{η}_{ω , θ}^{( 1 )}} = {c}_{ω , θ}^{( 1 )} ( z ) cos θ + {c}_{ω , θ}^{( 2 )} ( z ) sin 2 θ + {c}^{( 4 )} ( z ) {sin}^{2} θ , \qquad ( 19 )$$

$${H}_{{υ}_{ω , θ}}^{s} ( z ) = \frac{{υ}_{ω , θ}^{( 1 )} ( z )}{{η}_{ω , θ}^{( 1 )}} = {c}_{ω , θ}^{( 1 )} ( z ) sin θ + {c}_{ω , θ}^{( 3 )} ( z ) sin 2 θ + {c}_{ω , θ}^{( 4 )} ( z ) {cos}^{2} θ , \qquad ( 20 )$$

$${H}_{{ω}_{ω , θ}}^{s} ( z ) = \frac{{ω}_{ω , θ}^{( 1 )} ( z )}{{η}_{ω , θ}^{( 1 )}} = {c}_{ω , θ}^{( 6 )} , \qquad ( 21 )$$

$${H}_{{p}_{ω , θ}}^{s} ( z ) = \frac{{p}_{ω , θ}^{( 1 )} ( z )}{{η}_{ω , θ}^{( 1 )}} = {c}_{ω , θ}^{( 7 )} ( z ) + {c}_{ω , θ}^{( 8 )} ( z ) cos θ + {c}_{ω , θ}^{( 9 )} ( z ) sin θ , \qquad ( 22 )$$

where θ may be the wave direction, and

$${c}_{ω , θ}^{( i )} ( {z}_{0} )$$

may be discrete coefficients calculated via the numerical solution of the Rayleigh equation per, for example, discrete frequency co, discrete wave direction θ, and at z₀ sea level.

$${c}_{ω , θ}^{( 1 )} ( {z}_{0} ) = \frac{\frac{\partial {ω}_{ω , θ}^{( 1 )} ( {z}_{0} )}{{\partial }_{z}} {ω}_{{d}_{ω , θ}} ( 0 )}{{k}_{ω , θ} {ω}_{ω , θ}^{( 1 )}} , \qquad ( 23 )$$

$${c}_{ω , θ}^{( 2 )} ( {z}_{0} ) = \frac{\frac{\partial {υ}^{( 0 )} ( {z}_{0} )}{{\partial }_{z}} {ω}_{ω , θ}^{( 1 )} ( {z}_{0} ) {ω}_{{d}_{ω , θ}} ( 0 )}{2 {ω}_{ω , θ}^{( 1 )} ( 0 ) {ω}_{{d}_{ω , θ}} ( {z}_{0} )} , \qquad ( 24 )$$

$${c}_{ω , θ}^{( 3 )} ( {z}_{0} ) = \frac{\frac{\partial {u}^{( 0 )} ( {z}_{0} )}{{\partial }_{z}} {ω}_{ω , θ}^{( 1 )} ( {z}_{0} ) {ω}_{{d}_{ω , θ}} ( 0 )}{2 {ω}_{ω , θ}^{( 1 )} ( 0 ) {ω}_{{d}_{ω , θ}} ( {z}_{0} )} , \qquad ( 25 )$$

$${c}_{ω , θ}^{( 4 )} ( {z}_{0} ) = \frac{\frac{\partial {u}^{( 0 )} ( {z}_{0} )}{{\partial }_{z}} {ω}_{ω , θ}^{( 1 )} ( {z}_{0} ) {ω}_{{d}_{ω , θ}} ( 0 )}{{ω}_{ω , θ}^{( 1 )} ( 0 ) {ω}_{{d}_{ω , θ}} ( {z}_{0} )} = - 2 {c}_{ω , θ}^{( 3 )} ( {z}_{0} ) , \qquad ( 26 )$$

$${c}_{ω , θ}^{( 5 )} ( {z}_{0} ) = \frac{\frac{\partial {υ}^{( 0 )} ( {z}_{0} )}{{\partial }_{z}} {ω}_{ω , θ}^{( 1 )} ( {z}_{0} ) {ω}_{{d}_{ω , θ}} ( 0 )}{{ω}_{ω , θ}^{( 1 )} ( 0 ) {ω}_{{d}_{ω , θ}}} = - 2 {c}_{ω , θ}^{( 2 )} ( {z}_{0} ) , \qquad ( 27 )$$

$${c}_{ω , θ}^{( 6 )} ( {z}_{0} ) = \frac{- i {ω}_{ω , θ}^{( 1 )} ( {z}_{0} ) {ω}_{{d}_{ω , θ}} ( 0 )}{{ω}_{ω , θ}^{( 1 )} ( 0 )} , \qquad ( 28 )$$

$${c}_{ω , θ}^{( 7 )} ( {z}_{0} ) = \frac{{ρ}^{( 0 )} ( {z}_{0} ) {ω}_{{d}_{ω , θ}} ( 0 )}{{k}_{ω , θ}} {c}_{ω , θ}^{( 1 )} ( {z}_{0} ) , \qquad ( 29 )$$

$${c}_{ω , θ}^{( 8 )} ( {z}_{0} ) = \frac{2 {ρ}^{( 0 )} ( {z}_{0} ) {ω}_{{d}_{ω , θ}} ( {z}_{0} )}{{k}_{ω , θ}} {c}_{ω , θ}^{( 3 )} ( {z}_{0} ) , \qquad ( 30 )$$

$${c}_{ω , θ}^{( 9 )} ( {z}_{0} ) = \frac{2 {ρ}^{( 0 )} ( {z}_{0} ) {ω}_{{d}_{ω , θ}} ( {z}_{0} )}{{k}_{ω , θ}} {c}_{ω , θ}^{( 3 )} ( {z}_{0} ) . \qquad ( 31 )$$

In one example for the operation of ADCP in AST configuration, the oscillatory velocities u⁽¹⁾, v⁽¹⁾ may be related to the sea elevation q. In the following example, not as done in potential theory, the relations between the sea elevation and the horizontal oscillatory velocities will be accounting for the current velocity profiles u⁽⁰⁾ and v⁽⁰⁾). Since the sea elevation q, the vertical oscillatory velocity w⁽¹⁾, and the pressure p⁽¹⁾ are all indicating the vertical wave oscillations in z, they may all be considered as q record with the corresponding transfer function

$${H}_{η}^{s}$$

in a general notation, as

$${H}_{{u}_{ω , θ}}^{s} ( z ) , and {H}_{{υ}_{ω , θ}}^{s} ( z )$$

may all be wave oscillation parameters in the x,y direction, respectively, and not necessarily the oscillatory velocities (like oscillatory accelerations, etc.).

$$η = {{\int }^{π}}_{- π} {{\int }^{∞}}_{0} {H}_{η}^{s} ( ω , θ ) exp [ i ( {k}_{x} x + {k}_{y} y - ω t + ϵ ) ] Z ( \partial ω , \partial θ ) , \qquad ( 32 )$$

$$u = {{\int }^{π}}_{- π} {{\int }^{∞}}_{0} {H}_{u}^{s} ( ω , θ ) exp [ i ( {k}_{x} x + {k}_{y} y - ω t + ϵ ) ] Z ( \partial ω , \partial θ ) , \qquad ( 33 )$$

$$v = {{\int }^{π}}_{- π} {{\int }^{∞}}_{0} {H}_{υ}^{s} ( ω , θ ) exp [ i ( {k}_{x} x + {k}_{y} y - ω t + ϵ ) ] Z ( \partial ω , \partial θ ) . \qquad ( 34 )$$

In these equations, kₓ=k cos θ, and k_{y}=k sin θ. In addition, Z(dω, dθ) may be a complex number. Its absolute value may yield the wave amplitude, while its arguments may be the phases for x=y=t=0.

It is to be noted that the power density spectrum may be defined as S(ω, θ)∂ω∂θ= [symbol] Z(dω, dθ)Z*(dω, dθ) [symbol] , with the complex conjugate denoted by *.

The three auto-cross spectra functions, and the three cross-spectra functions are now dependent on the new derived transfer functions as follows:

$$\begin{matrix}{S}_{ηη} ( ω ) = {{\int }^{π}}_{- π} {H}_{η}^{s} ( ω , θ , z ) {H}_{η}^{s★} ( ω , θ , z ) S ( ω , θ ) \partial θ = \\ S ( ω ) ,\end{matrix} \qquad ( 35 )$$

$${S}_{uu} ( ω ) = {{\int }^{π}}_{- π} {H}_{u}^{s} ( ω , θ , z ) {H}_{u}^{s★} ( ω , θ , z ) S ( ω , θ ) \partial θ , \qquad ( 36 )$$

$${S}_{υ u} ( ω ) = {{\int }^{π}}_{- π} {H}_{υ}^{s} ( ω , θ , z ) {H}_{υ}^{s★} ( ω , θ , z ) S ( ω , θ ) \partial θ , \qquad ( 37 )$$

$${S}_{η u} ( ω ) = {{\int }^{π}}_{- π} {H}_{η}^{s} ( ω , θ , z ) {H}_{u}^{s★} ( ω , θ , z ) S ( ω , θ ) \partial θ , \qquad ( 38 )$$

$${S}_{η u} ( ω ) = {{\int }^{π}}_{- π} {H}_{η}^{s} ( ω , θ , z ) {H}_{υ}^{s★} ( ω , θ , z ) S ( ω , θ ) \partial θ , \qquad ( 39 )$$

$${S}_{u υ} ( ω ) = {{\int }^{π}}_{- π} {H}_{u}^{s} ( ω , θ , z ) {H}_{υ}^{s★} ( ω , θ , z ) S ( ω , θ ) \partial θ , \qquad ( 40 )$$

Since the spread function may be described as a reconstruction of a Fourier series, with unknown Fourier coefficients, âₙ,\hat{b}ₙ the directional power density spectrum may be expressed as a function of those unknown Fourier coefficients

$$\begin{matrix}S ( ω , θ ) = S ( ω ) G ( ω , θ ) = \\ \frac{S ( ω )}{π} [ \frac{1}{2} + {{\sum }^{∞}}_{n = 1} ( {\hat{a}}_{n} cos ( n θ ) + {\hat{b}}_{n} sin ( n θ ) ) ] .\end{matrix} \qquad ( 44 )$$

The horizontal velocity transfer functions may be of real numbers, and hence

$${H}_{u}^{s} = {H}_{u}^{s ★} , {H}_{υ}^{s} = {H}_{υ}^{s ★} .$$

Substituting (41) in (35)-(40) and using discrete notation for certain frequency co, may yield six expressions dependent on the unknown Fourier coefficients:

$${[ {S}_{η η} ]}_{ω} = {S}_{ω} \text{?} \frac{1}{π} \text{?} [ \frac{1}{2} + {\sum }_{n} ( {\hat{a}}_{n} cos ( n θ ) + {\hat{b}}_{n} sin ( n θ ) ) ] Δ θ , \qquad ( 42 )$$

$${[ \text{?} ]}_{ω} = {S}_{ω} \text{?} \frac{1}{π} [ \frac{1}{2} + {\sum }_{n} ( {\hat{a}}_{n} cos ( n θ ) + {\hat{b}}_{n} sin ( n θ ) ) ] Δ θ , \qquad ( 44 )$$

$${[ \text{?} ]}_{ω} = {S}_{ω} \text{?} \frac{1}{π} [ \frac{1}{2} + {\sum }_{n} ( {\hat{a}}_{n} cos ( n θ ) + {\hat{b}}_{n} sin ( n θ ) ) ] Δ θ , \qquad ( 45 )$$

$${[ \text{?} ]}_{ω} = {S}_{ω} \text{?} \frac{1}{π} [ \frac{1}{2} + {\sum }_{n} ( {\hat{a}}_{n} cos ( n θ ) + {\hat{b}}_{n} sin ( n θ ) ) ] Δ θ , \qquad ( 46 )$$

$${[ \text{?} ]}_{ω} = {S}_{ω} \text{?} \frac{1}{π} [ \frac{1}{2} + {\sum }_{n} ( {\hat{a}}_{n} cos ( n θ ) + {\hat{b}}_{n} sin ( n θ ) ) ] Δ θ \text{?} \qquad ( 47 )$$

$$\text{?} \text{indicates text missing or illegible when filed}$$

The first auto-spectra equation (42) may denote the energy spectrum S_{ω}, and may be employed in scaling all the other expressions.

In some cases, equations (43), (44) may be combined into one equation.

In some cases like the one given for an ADCP employing AST beam, four independent equations are required to solve n=2, and the other three equations may be of the cross spectra expressions (45)-(47). Therefore, the total number of equations is four and they may be arranged in a linear matrix form to solve âₙ,\hat{b}ₙ coefficients per frequency,

$${{[ \begin{matrix}{a}_{1 uu} - \text{?} & {b}_{1 uu} - \text{?} & {a}_{2 uu} - \text{?} & {b}_{2 uu} - \text{?} \\ {a}_{1 μ u} & {b}_{1 μ u} & {a}_{2 μ u} & {b}_{2 μ u} \\ \text{?} & \text{?} & \text{?} & \text{?} \\ \text{?} & \text{?} & \text{?} & \text{?}\end{matrix} ]}_{ω} [ \begin{matrix}{\hat{a}}_{1} \\ {\hat{b}}_{1} \\ {\hat{a}}_{2} \\ {\hat{b}}_{2}\end{matrix} ]}_{ω} = {[ \begin{matrix}\frac{\text{?} - \text{?}}{{S}_{ω} Δ θ} - ( {a}_{0 , uu} - \text{?} \\ \frac{\text{?}}{{S}_{ω} Δ θ} - \text{?} \\ \frac{\text{?}}{{S}_{ω} Δ θ} - \text{?} \\ \frac{\text{?}}{{S}_{ω} Δ θ} - \text{?}\end{matrix} ]}_{ω} . \qquad ( 48 )$$

$$Here ,$$

$$\text{?} = \frac{1}{2 π} \text{?} , \qquad ( 49 )$$

$$\text{?} = \frac{1}{π} \text{?} cos n θ , \qquad ( 50 )$$

$$\text{?} = \frac{1}{π} \text{?} sin n θ , \qquad ( 51 )$$

$$\text{?} \text{indicates text missing or illegible when filed}$$

where k, and l may be the sensor index which is one of the vertical sensors η, w, p, and the two orthogonal horizontal velocities u, v.

In some cases u,v can be replaced in other horizontal wave parameters like wave horizontal accelerations, etc.

The Fourier coefficients âₙ,\hat{b}ₙ may be solved per frequency from (48) via the numerically calculated known transfer functions Hₖ^{s} (19), H_{f}^{s} (20), and the c⁽ⁱ⁾ coefficients (23)-(27), for z=z₀. The solution of may then be substituted in (41) to yield the wave directional power density spectrum.

Following all the above, the obtained spectrum would account for the shearing currents.

By way of a non-limiting example (presented merely for purposes of better understanding the disclosed subject matter and not in any way intended to limit its scope), the presently disclosed subject matter, explained hereinbefore, was tested for the case of single frequency waves propagating in a predetermined spread.

Initially, the total energy of the single frequency waves was set to an arbitrary energy of 30 m²/Hz, whereas the energy spectra were distributed to predetermined directions according to a spread function G(O) of Longuet-Higgins (equation 52 below). The theoretical spread common in wave simulations was compared with measurements common in wave simulations.

$$G ( θ ) = {G}_{0} {cos}^{2 s} ( \frac{θ - {θ}_{0}}{2} ) , {G}_{0} = \frac{{2}^{2 s - 1} {Γ}^{2} ( s + 1 )}{π Γ ( 2 s + 1 )} . \qquad ( 52 )$$

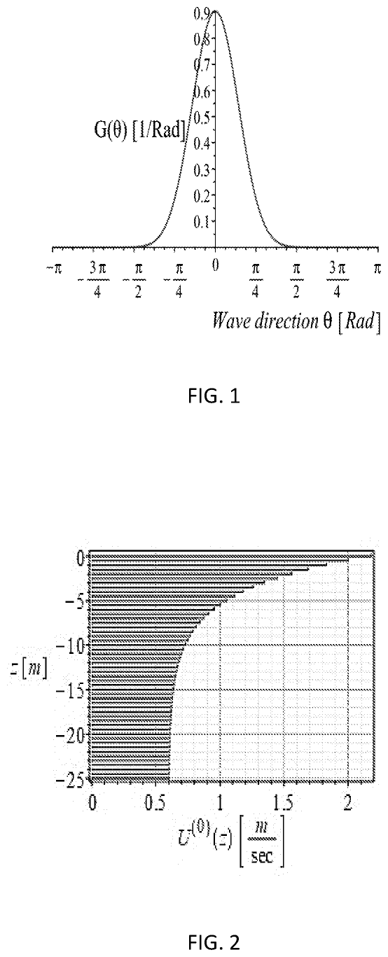

The main direction θ₀ was set to 0⁰ corresponding to waves propagating from west to east, the power was set to s=10, a relatively narrow band corresponding to wind waves directional spread of the simulated wave peak period (as illustrated in FIG. 1), and the waves were propagating in the presence of zero order current profile U⁽⁰⁾(z), inclined to the waves mean propagation direction in 72⁰, corresponding to 1:3 ratio of its horizontal components u⁽⁰⁾(z), v⁽⁰⁾(z). In addition, the zero-order current U⁽⁰⁾(z) was chosen to be a superposition of a constant and an exponential shaped profile current (as illustrated in FIG. 2) given as

$${U}^{( 0 )} ( z ) = \sqrt{{u}^{{( 0 )}^{2}} ( z ) + {υ}^{{( 0 )}^{2}} ( z )} = \sqrt{2.5} exp ( 0.25 z ) + \sqrt{0.4} . \qquad ( 53 )$$

Next, three data sets, as could have been recorded by an ADCP instrument accounting for the ambient current profile η, u, v, were simulated. The wave amplitudes

$${η}_{ω , θ}^{( 1 )}$$

were calculated according to their relation to the PDS

$${η}_{ω , θ} = \sqrt{2 {S}_{ω , θ}^{2} Δ ω Δ θ}$$

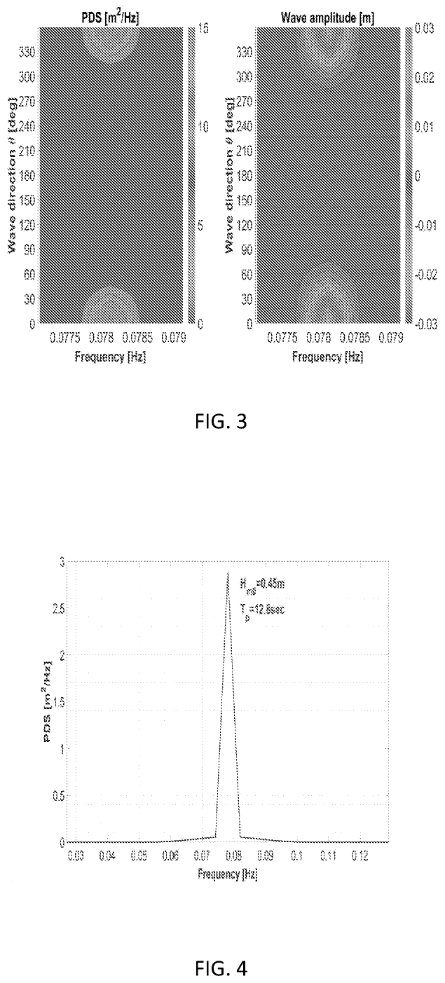

(the directional PDS input of the single frequency waves simulation is illustrated in FIG. 3), and together with the ambient current profiles u⁽⁰⁾(z), v⁽⁰⁾(z), were generated as input for the simulation.

The Rayleigh BVP was solved per each frequency and direction. The solution yielded the wave numbers k_{ω,θ} and the vertical velocity profiles

$${w}_{ω , θ}^{( 1 )} ( z ) .$$

The solutions (profiles) of

$${w}_{ω , θ}^{( 1 )} ( z )$$

corresponding to the normalization of the boundary condition (48) were scaled to the actual wave amplitudes, and the first order horizontal oscillatory velocities

$${u}_{ω , θ}^{( 1 )} ( z ) , {υ}_{ω , θ}^{( 1 )} ( z )$$

could be calculated via equations (51)-(52).

A vertical profile step of Δz=0.5 m was adopted for a total depth of h=25 m. Three data sets of duration of T=2048 sec were sampled at 2 Hz, and the directional angular step was set to Δθ=1⁰ to eliminate artifacts of discretization.

As the data processing was carried out for ADCP's velocity record, the first order horizontal velocities were computed at z≈−0.1h (˜2 m/25 m), as common in actual ADCP measurement processing due to inaccurate back scatter from the upper layer caused by air bubbles. The time series of the sea elevation q(t), the east velocity u(t)|_{z}_{^{0≈}}_{-0.1}h, and the north velocity v(t)|_{z}_{^{0=−0.1h}} were obtained by employing Inverse Fast Fourier Transform (IFFT) for predefined random phases OCo.

The data processing of the estimated directional spread Ŝf,θ was carried out twice. The first simulation employed potential wave transfer functions, where the Fourier coefficients are calculated according to potential theory equations (54)-(57).

$${a}_{1} = \frac{1}{S ( ω )} {\int }_{- π}^{π} S ( ω , θ ) cos θ d θ = \frac{{K}_{p} \text{?}}{\text{?} {S}_{pp}} , \qquad ( 54 )$$

$${a}_{2} = \frac{1}{S ( ω )} {\int }_{- π}^{π} S ( ω , θ ) cos 2 θ d θ = {( \frac{{K}_{p}}{\text{?}} )}^{2} \frac{\text{?} - \text{?}}{{S}_{pp}} , \qquad ( 55 )$$

$${b}_{1} = \frac{1}{S ( ω )} {\int }_{- π}^{π} S ( ω , θ ) sin θ d θ = \frac{{K}_{p} \text{?}}{\text{?} {S}_{pp}} , \qquad ( 56 )$$

$${b}_{2} = \frac{1}{S ( ω )} {\int }_{- π}^{π} S ( ω , θ ) sin 2 θ d θ = {( \frac{{K}_{p}}{\text{?}} )}^{2} \frac{2 \text{?}}{{S}_{pp}} . \qquad ( 57 )$$

$$\text{?} \text{indicates text missing or illegible when filed}$$

The second simulation employed the presently disclosed subject matter, in which the mean current velocity profile is accounted for in determining the new obtained numerical transfer functions (19), (20), and the Fourier coefficients are solved according to the relations between the cross-spectra products (48)-(51). The c⁽ⁱ⁾ coefficients (23)-(27) were derived for all frequencies and directions.

The number of realizations was set to N=10,000 in both simulations to eliminate, as much as possible, phase influence within the calculation time and computational limit. Idyllically, the number of realizations can be even greater in order to further decrease the error of the wave spread function.

$${\hat{S}}_{f , θ} = \frac{1}{N} {\sum }_{i = 1}^{N} {( {S}_{f , θ} )}_{i} \qquad ( 58 )$$

It is to be noted that due to the linearity of the solution, the conclusion for the monochromatic wave applies for a full spectrum of regular random sea.

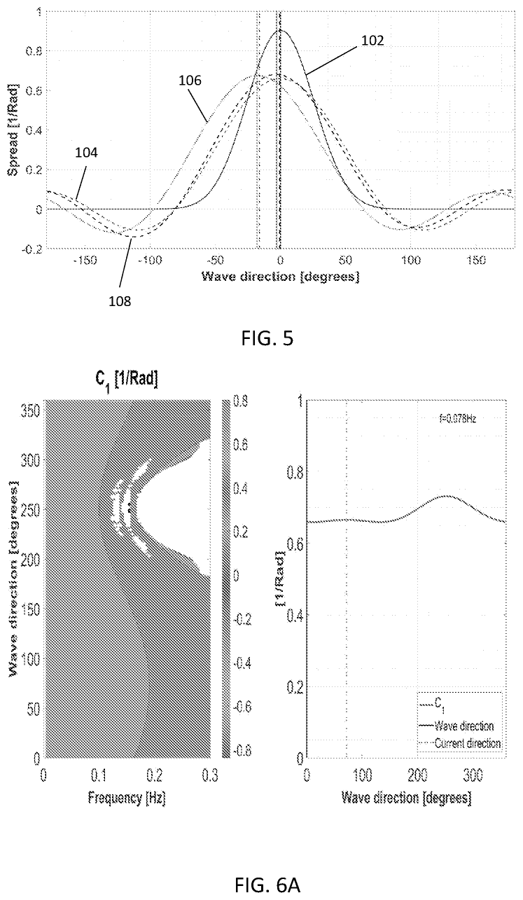

An obtained 1D PDS, which is only dependent on the sea elevation time series η(t), indicated the certain predetermined amount of wave energy (illustrated in FIG. 4). As seen in FIG. 4, the energy is concentrated and centered around a predetermined frequency corresponding to the monochromatic wave period of T=12.8 sec. Little energy shifting due to the random phases may be observed.

Next, resulted spread functions for the case study of ambient current in ratio u⁽⁰⁾:v⁽⁰⁾ of 1:3 for the different methods are shown in FIG. 5. As shown in FIG. 5, (i) the solid line, denoted 102, shows the original spread, (ii) the dashed line, denoted 104, shows a reconstruction of the spread by employing Fourier coefficients of the input up to the second order (N=2), to show the limits of the spread estimation for only three records (η,u,v), (iii) the dash line, denoted 106, shows common potential data processing, and (iv) the dash line, denoted 108, shows the obtained spread for the method data processing of the presently disclosed subject matter, accounting for the shearing current. The difference between the original input spread peak and mean to the one obtained after the data processing was calculated and is denoted as Δθₘ^{p} and

$$Δ {θ}_{m}^{s}$$

for the potential and the shearing currents methods respectively. It is shown that even for the potential waves there is a deviation in the mean direction estimation. This case study does not have symmetric properties. Most of the current propagates in perpendicular direction to the wave mean direction. The inclination of the current to the mean wave direction influences significantly the obtained spread, while employing common potential wave theory data processing. In particular, the differences in peak direction computed by the two methods yield a 16.3⁰ while, and the new shearing current data processing is significantly more accurate providing

$$Δ {θ}_{m}^{s} = {0.7}^{0} .$$

This confirms that the shearing currents data processing method of the presently disclosed subject matter is superior compared to the potential data processing. The directional deviation Δθ^{m} is much smaller and significantly more accurate than the one of the potential data processing.

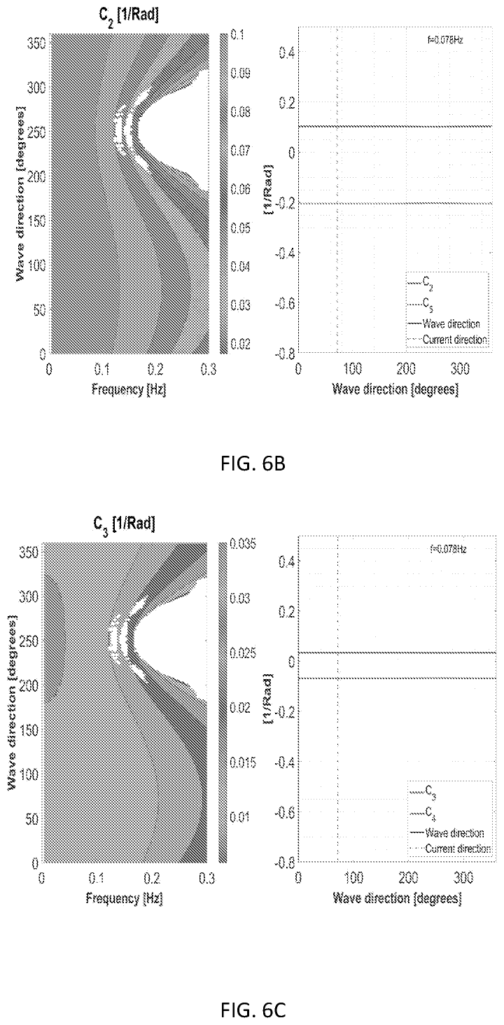

The full Rayleigh solution per frequency and direction is presented for this case study. The c⁽¹⁾, c⁽²⁾, and c⁽³⁾ coefficients were mapped and illustrated in FIGS. 6A-6C, respectively.

Since there is a linear dependency between the wave's amplitudes and the wave's oscillatory velocities, the c⁽ⁱ⁾ coefficients are dependent only in the ambient currents u⁽⁰⁾ and v⁽⁰⁾, and are the same for any original wave amplitude spectrum. As shown in FIGS. 6A-6C, the mapping of the c⁽ⁱ⁾ coefficients shows minimal and maximal values in the current inclination direction and in the opposed current direction. The transfer functions for the single frequency waves calculated while accounting for shearing currents are very different than the potential transfer ones. This clearly shows why there is a significant error in the estimated directional spectrum, derived according to the potential wave theory. In addition, it can be noted that the potential part of the solution given in c⁽¹⁾ values is still the most dominant compared to the shearing current influence given in c⁽²⁾ and c⁽³⁾.

From FIGS. 6A-6C, it is shown that for higher frequencies, those coefficients change more significantly along the different directions and the coefficients' solution indicates that deep sea waves of short length have a curvature correction solution and are highly dependent on the wave direction. For waves propagating against the current, the c⁽ⁱ⁾ coefficients are strongly dependent on the wave frequencies. No-solution at that range indicates that blocking occurs (a situation in which strong currents do not allow for the development of specific waves).

Another aspect of these results is that the Rayleigh BVP solver might yield solutions of negative wave numbers k, or ignore existing solutions. It makes sense that the solver finds negative k values for waves propagating against the current, and it is actually indicating waves propagating in a reversed direction, which is the current direction.

The new derived transfer functions accounting for the shearing currents

$${H}_{u}^{s} and {H}_{υ}^{s}$$

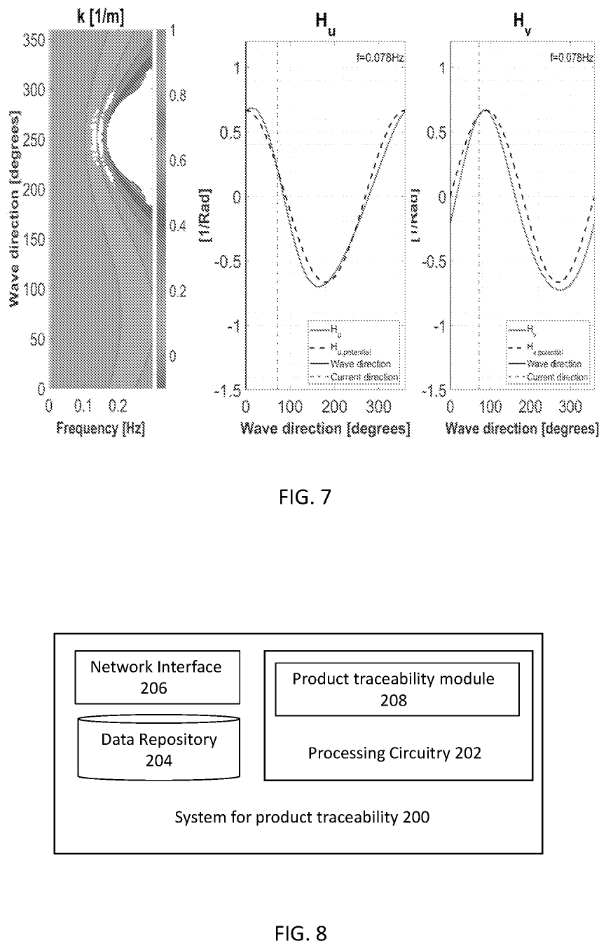

are plotted for the wave frequency of 0.078 Hz, and were compared to their potential ones Hᵤ^{p} and Hᵥ^{p}, respectively. Those results are illustrated in FIG. 7.

Attention is now drawn to a description of the components of the system for determining design parameters for maritime infrastructure 200.

FIG. 8 is a block diagram schematically illustrating one example of the system for determining design parameters for maritime infrastructure 200, in accordance with the presently disclosed subject matter.

In accordance with the presently disclosed subject matter, the system for determining design parameters for maritime infrastructure 200 (also interchangeably referred to herein as “system 200”) can comprise a network interface 206. The network interface 206 (e.g., a network card, a Wi-Fi client, a Li-Fi client, 3G/4G/5G client, or any other component), enables system 200 to communicate over a network with external systems and handles inbound and outbound communications from such systems. For example, system 200 can receive, through network interface 206, a plurality of independent wave measurements of a body of a fluid, obtained over a period of time (explained in further detail hereinafter in relation to FIG. 9).

System 200 can further comprise or be otherwise associated with a data repository 204 (e.g., a database, a storage system, a memory including Read Only Memory—ROM, Random Access Memory—RAM, or any other type of memory, etc.) configured to store data. Some examples of data that can be stored in the data repository 204 include:
One or more ambient shearing current profiles;
One or more distinct locations of a body of fluid;
One or more ambient current values and directions;
One or more wave directional spectra;
One or more design parameters of one or more maritime infrastructures;
One or more placements of one or more marine infrastructures; and
One or more assessments of one or more marine infrastructures.

Data repository 204 can be further configured to enable retrieval and/or update and/or deletion of the stored data. It is to be noted that in some cases, data repository 204 can be distributed, while the system 200 has access to the information stored thereon, e.g., via a wired or wireless network to which system 200 is able to connect (utilizing its network interface 206).

System 200 further comprises processing circuitry 202. Processing circuitry 202 can be one or more processing units (e.g., central processing units), microprocessors, microcontrollers (e.g., microcontroller units (MCUs)) or any other computing devices or modules, including multiple and/or parallel and/or distributed processing units, which are adapted to independently or cooperatively process data for controlling relevant system 200 resources and for enabling operations related to system's 200 resources.

The processing circuitry 202 comprises a design parameters determination module 208, configured to perform a design parameters determination process 300, as further detailed herein, inter alia with reference to FIG. 9.

Turning to FIG. 9 there is shown a flowchart illustrating one example of operations carried out by the system for determining design parameters for maritime infrastructure 200, in accordance with the presently disclosed subject matter.

Accordingly, the system for determining design parameters for maritime infrastructure 200 (also interchangeably referred to hereafter as “system 200”) can be configured to perform design parameters determination process 300, e.g., using design parameters determination module 208.

For this purpose, system 200 obtains: (a) a plurality of independent wave measurements of a body of fluid, obtained over a period of time, and (b) a respective ambient shearing current profile (block 302). The plurality of independent wave measurements may be obtained at one or more distinct locations of the body of fluid (e.g., location found within the body of fluid, location found above the body of fluid, and the like), by a respective sensor (e.g., a single sensor or a measurement instrument including a plurality of sensors), whereas the respective ambient shearing current profile may be obtained based on measured and/or assumed values and directions of one to more ambient currents, at different locations within the body of fluid, related to the one or more distinct locations. For example, the plurality of independent wave measurements may be obtained at three distinct locations on the surface of the body of fluid, by a measurement instrument placed at the bottom of the body of fluid, including three respective sensors, whereas the respective ambient shearing current profile may be obtained based on average values and directions (measured, for example, using an Acoustic Doppler Current Profiler (ACDP)) of horizontal ambient shearing currents found at different depth points between the bottom of the body of fluid and the fluid's surface, along a water column located proximate to the three distinct locations.

The independent wave measurements, which may be measured either directly, e.g., by performing temporal measurements, spatial measurements, and the like, or indirectly, e.g., by performing physical, geometrical, or chemical measurements, may involve measurements of fluid of the body of fluid and/or measurements of fluid found above the body of fluid. In one example, the body of fluid may be a body of water (e.g., a lake, a sea, an ocean, etc.) and the independent wave measurements may involve measurements of water of a body of water (e.g., the lake, the sea, the ocean, etc.) and/or measurements of the air and/or wind found above the body of water (e.g., the lake, the sea, the ocean, etc.).

In some cases, the independent wave measurements may be sea elevation measurements. In other cases, the independent wave measurements may involve measurements of particles of any kind found within the body of fluid (for example, plankton, sediments, carbohydrates, amino acids, atmospheric gases, and the like).

In some cases, the respective sensor performing the direct and/or indirect measurements mentioned hereinbefore may, for example, be or be assembled of any one of: one or more ADCPs (Acoustic Doppler Current Profiler), one or more wave buoys, one or more wave drifters, one or more pressure gauges, one or more wave staff, one or more current meters, one or more current profilers, one or more tilt meters, one or more acceleration meters, one or more compasses, one or more compasses sea images, one or more compasses PTVs (particle tracking velocimetry), one or more compasses PIVs (particle image velocimetry), one or more compasses thermometers, one or more LIDARs (Light Detection and Ranging), one or more Radars, one or more sonars, one or more turbidity sensors, one or more mooring risers, one or more shadowgraphs, one or more hot wires and films, one or more strain-gauges, one or more sonic winds, and the like.

In some cases, the respective sensor may be placed at the distinct location. In other cases, the respective sensor may be placed at a location remote from the distinct location(s).

Next, based on the wave measurements and the ambient shearing currents profile, system 200 assesses wave directional spectra characterizing flow regime of waves of the body of fluid (e.g., waves found on the fluid surface, internal waves found within the body of the fluid, and the like), while accounting for the effects of the ambient shearing currents during the wave measurements' period of time (block 304). The wave directional spectra, which may be, for example, any of: power density spectra (PDS), wave amplitude spectra (WAS), one-dimension spectra, and the like, may be assessed, in one example, by calculating transfer functions, while accounting for the ambient shearing currents profile, as described hereinbefore in relation to FIGS. 1-7.

In some cases the wave directional spectra may include spatial wave growth coefficients, spatial wave decay coefficients, or a combination thereof.

Based on the assessed wave directional spectra, system 200 determines one or more design parameters of a maritime infrastructure (block 306). The one or more design parameters may include, for example, one or more height parameters, one or more width parameters, one or more angle parameters, one or more weight parameters, and the like, which may serve as a basis for designing a given maritime infrastructure.

In one example, the one or more design parameters may be utilized to determine placement of maritime infrastructure (e.g., a ship, a rig, a breakwater, an offshore wind structure, a subsea pipeline, a quay wall, ports, jetties, quays, wharves, land reclamations, a desalination plant, artificial islands, marine intakes and outlets, marine agriculture infrastructure). In another example, the one or more design parameters may be utilized for maritime assessment (e.g., a beach morphology design, an environmental impact, cliff erosion assessments and predictions, a climate change impact study, a forecast physical modeling, a hind-cast physical modeling, a forecast numerical modeling, or a hind-cast numerical modeling).

By way of a non-limiting example, presented merely for purposes of better understanding the disclosed subject matter and not in any way intended to limit its scope, FIG. 10 illustrates an exemplary flowchart illustrating an example of operations carried out by the system for determining design parameters for maritime infrastructure 200, in accordance with the presently disclosed subject matter. As shown in FIG. 10, system 200 obtains: (i) measurements of sea elevation, (ii) measurements of pressure, and (iii) the current profile (all marked by box 400), and returns the wave power density spectrum (marked by box 402).

### EXAMPLES

The following example is not meant to limit the scope of the claims in any way. The following example is put forth so as to provide those of ordinary skill in the art with a complete disclosure and description of how to make and use the presently disclosed subject matter, and is not intended to limit the scope of said subject matter, nor is it intended to represent that the experiments below are all or the only experiments performed. Unless indicated otherwise, parts are parts by weight, molecular weight is weight average molecular weight, temperature is in degrees Centigrade, and pressure is at or near atmospheric.

### Example 1—Application of the Described Subject Matter on an ADCP Device

On Jan. 27, 2022, at 06:00, an ADCP device of Nortek's© Signature 1000 brand collected data offshore Tel Aviv at a water depth of 16 meters. The ADCP was mounted on the seabed in an up-looking position employing (a) a vertical acoustic surface tracking beam, and (b) four slanted beams. The vertical beam provided the sea elevation record, while the slanted beams provided the horizontal velocities record. The data was collected at a sampling frequency of 2 Hz. The new interpretation method described hereinbefore was implemented on the data collected for proof of concept purposes.

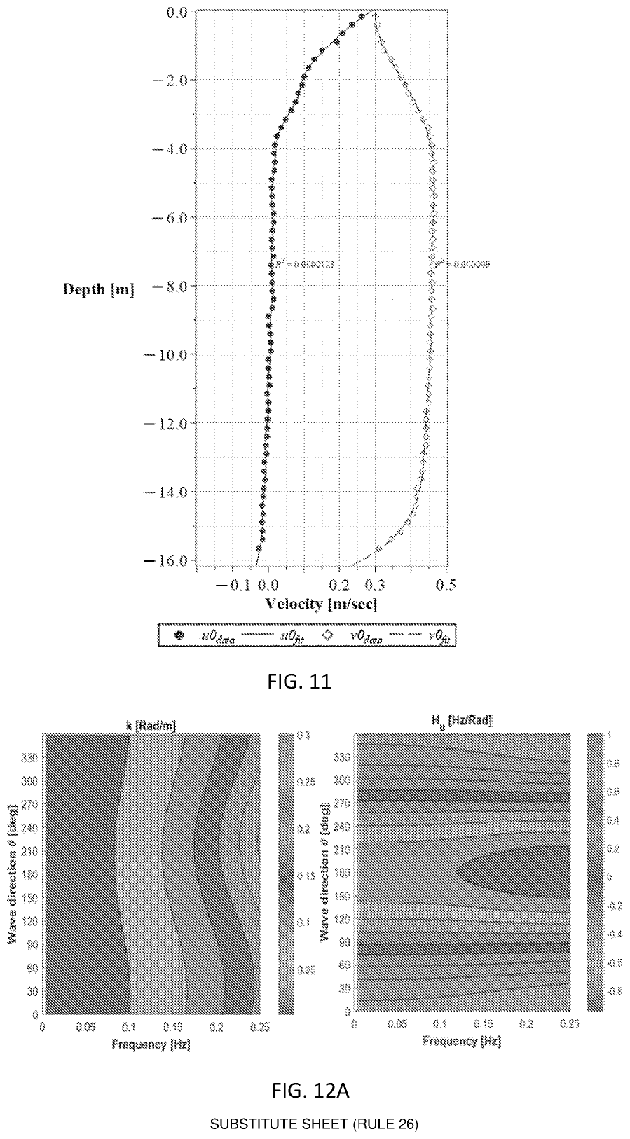

Initially, the horizontal velocities were averaged over 17 minutes, corresponding to the 4096 time series samples, and the zero-order velocity profile functions, u⁽⁰⁾ and v⁽⁰⁾, were fitted to the measurement points. FIG. 11 illustrates the averaged east and west horizontal velocities, u⁽⁰⁾ and v⁽⁰⁾, correspondingly. R² is the residual error of the nonlinear fitted function.

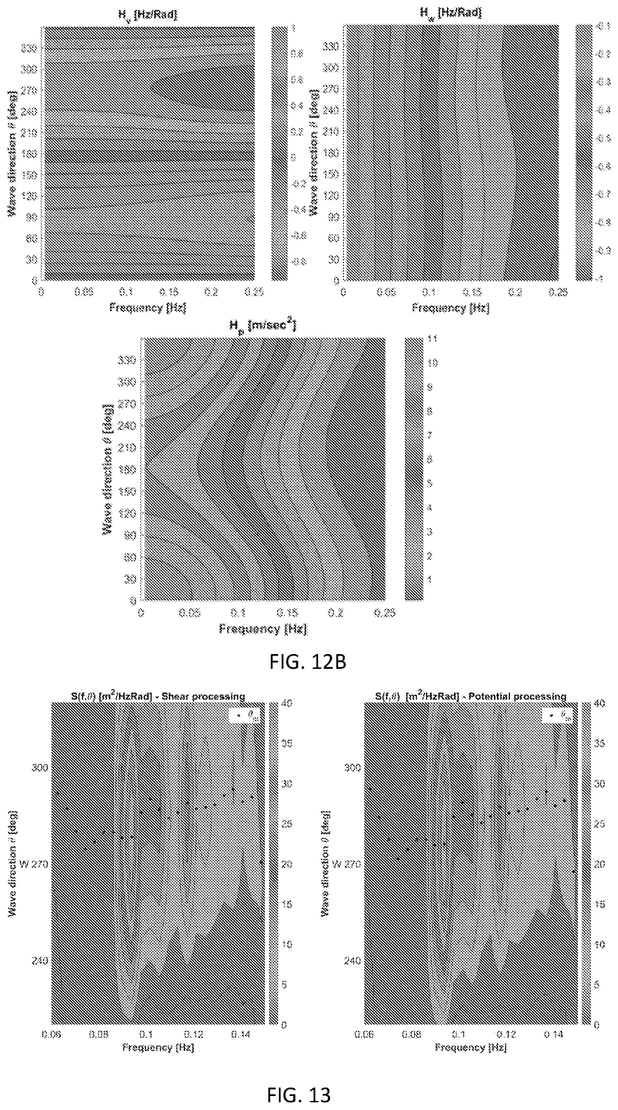

After solving the Rayleigh BVP per each wave direction and frequency, the dispersion relation and the numerical transfer function Hᵢ were derived. FIGS. 12A-12B illustrates the dispersion relation k(f, θ) and the numerical transfer functions Hᵢ(f, θ) accounting for the shearing current profile for January 27th, at 6:00 a.m., offshore Tel Aviv at a depth of 16 meters. The transfer functions were derived for the east and west horizontal velocities (u,v), the vertical velocity (w), and the pressure (p).

The Fourier coefficients for the Triplet sensor array (SUV) were estimated according to the new transfer functions, and the power density directional spectrum S(f, θ) and the spread function G(f, θ) were computed. FIG. 13 illustrates the directional power density spectrum S(f,θ) calculated according to the new interpretation method, presented hereinbefore, and according to the wave potential theory for the data collected on January 27th, at 6:00 a.m., offshore Tel Aviv at a depth of 16 meters. FIG. 14 illustrates the directional spread functions G(f, θ) calculated according to the new interpretation method, presented hereinbefore, and according to the wave potential theory for the data collected on January 27th, at 6:00 a.m., offshore Tel Aviv at a depth of 16 meters.

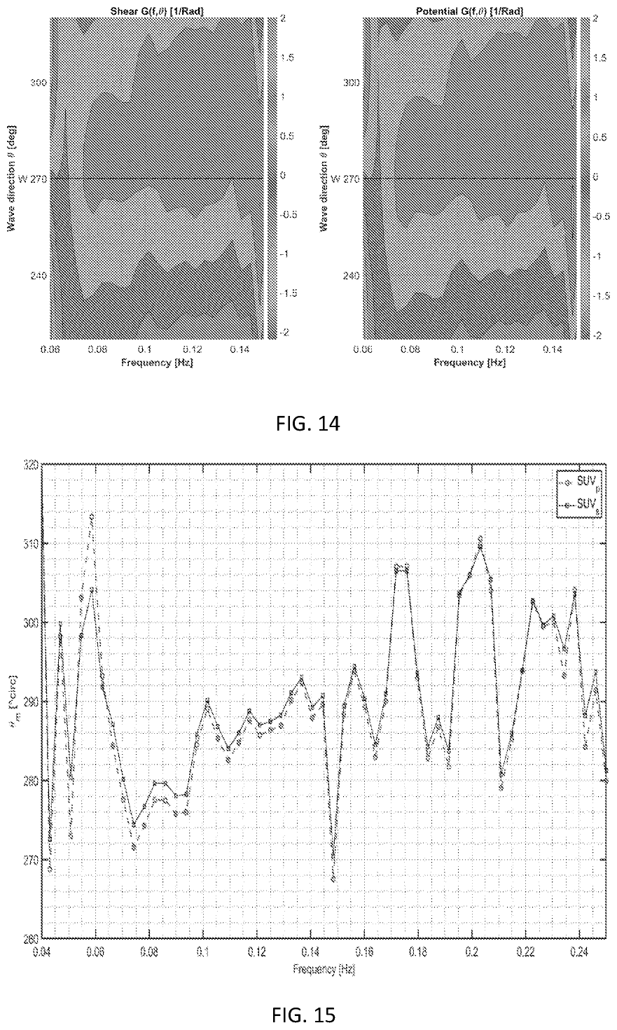

The wave mean direction θₘ was computed according to the first order Fourier coefficients as arctan(b₁/a₁). FIG. 15 illustrates the mean wave direction θₘ calculated according to the new interpretation method and according to the wave potential theory for the data collected on January 27th, at 6:00 a.m., offshore Tel Aviv at a depth of 16 meters.

It is to be noted, with reference to FIGS. 9 and 10, that some of the blocks can be integrated into a consolidated block or can be broken down to a few blocks and/or other blocks may be added. It is to be further noted that some of the blocks are optional. It should be also noted that whilst the flow diagram is described also with reference to the system elements that realizes them, this is by no means binding, and the blocks can be performed by elements other than those described herein.

It is to be understood that the presently disclosed subject matter is not limited in its application to the details set forth in the description contained herein or illustrated in the drawings. The presently disclosed subject matter is capable of other embodiments and of being practiced and carried out in various ways. Hence, it is to be understood that the phraseology and terminology employed herein are for the purpose of description and should not be regarded as limiting. As such, those skilled in the art will appreciate that the conception upon which this disclosure is based may readily be utilized as a basis for designing other structures, methods, and systems for carrying out the several purposes of the present presently disclosed subject matter.

It will also be understood that the system according to the presently disclosed subject matter can be implemented, at least partly, as a suitably programmed computer. Likewise, the presently disclosed subject matter contemplates a computer program being readable by a computer for executing the disclosed method. The presently disclosed subject matter further contemplates a machine-readable memory tangibly embodying a program of instructions executable by the machine for executing the disclosed method.

1. An interpretation method for determining placement parameters for maritime infrastructure comprising:
obtaining: (a) a plurality of independent wave measurements of a body of a fluid, obtained over a period of time, wherein each independent wave measurement is acquired at a distinct location of the body of fluid, by a respective sensor; and (b) a respective ambient shearing current profile, wherein the respective ambient shearing current profile is based on ambient current values and directions at different locations within the body of the fluid, related to the respective distinct location;
based on the wave measurements and the ambient shearing currents profile, assessing wave directional spectra characterizing flow regime of waves of the body of fluid, while accounting for the effects of the ambient shearing currents during the wave measurements' period of time; and
determining, based on the assessed wave directional spectra, one or more design parameters of the maritime infrastructure.

2. The interpretation method of claim 1, wherein design parameters are utilized to determine placement of the maritime infrastructure.

3. The interpretation method of claim 1, wherein design parameters are utilized for maritime assessment.

4. (canceled)

5. (canceled)

6. (canceled)

7. (canceled)

8. (canceled)

9. (canceled)

10. (canceled)

11. The interpretation method of claim 1, wherein: (a) the distinct location is a location found within the body of fluid, and (b) the wave measurements are measurements of fluid of the body of fluid.

12. The interpretation method of claim 1, wherein: (a) the distinct location is a location found above the body of fluid, and (b) the wave measurements are measurements of fluid found above the body of water.

13. (canceled)

14. (canceled)

15. The interpretation method of claim 1, wherein the different locations are depth points between the bottom of the body of fluid and the fluid's surface along a water column.

16. The interpretation method of claim 1, wherein the respective ambient shearing currents profile is either measured or assumed.

17. The interpretation method of claim 1, wherein the flow regime of waves includes either waves found on the fluid surface, internal waves found within the body of the fluid, or a combination thereof.

18. The interpretation method of claim 1, wherein the assessment of the wave directional spectra is performed by calculating transfer functions, while accounting for the ambient shearing currents profile.

19. (canceled)

20. A system for determining design parameters for maritime infrastructure, the system comprising a processing circuitry configured to:
obtain: (a) a plurality of independent wave measurements of a body of a fluid, obtained over a period of time, wherein each independent wave measurement is acquired at a distinct location of the body of fluid, by a respective sensor; and (b) a respective ambient shearing current profile, wherein the respective ambient shearing current profile is based on ambient current values and directions, at different locations within the body of the fluid, related to the respective distinct location;
based on the wave measurements and the ambient shearing currents profile, assess wave directional spectra characterizing flow regime of waves of the body of fluid, while accounting for the effects of the ambient shearing currents during the wave measurements' period of time; and
determine, based on the assessed wave directional spectra, one or more design parameters of the maritime infrastructure.

21. The system of claim 20, wherein design parameters are utilized to determine placement of the maritime infrastructure.

22. The system of claim 20, wherein design parameters are utilized for maritime assessment.

23. (canceled)

24. The system of claim 20, wherein the wave measurements involve measurements of particles of any kind found within the body of fluid.

25. (canceled)

26. (canceled)

27. (canceled)

28. (canceled)

29. (canceled)

30. The system of claim 20, wherein: (a) the distinct location is a location found within the body of fluid, and (b) the wave measurements are measurements of fluid of the body of fluid.

31. The system of claim 20, wherein: (a) the distinct location is a location found above the body of fluid, and (b) the wave measurements are measurements of fluid found above the body of water.

32. (canceled)

33. (canceled)

34. The system of claim 20, wherein the different locations are depth points between the bottom of the body of fluid and the fluid's surface along a water column.

35. The system of claim 20, wherein the respective ambient shearing currents profile is either measured or assumed.

36. The system of claim 20, wherein the flow regime of waves includes either waves found on the fluid surface, internal waves found within the body of the fluid, or a combination thereof.

37. The system of claim 20, wherein the assessment of the wave directional spectra is performed by calculating transfer functions, while accounting for the ambient shearing currents profile.

38. (canceled)

39. A non-transitory computer readable storage medium having computer readable program code embodied therewith, the computer readable program code, executable by at least one processor to perform an interpretation method for determining placement parameters for maritime infrastructure, the method comprising:
obtaining: (a) a plurality of independent wave measurements of a body of a fluid, obtained over a period of time, wherein each independent wave measurement is acquired at a distinct location of the body of fluid, by a respective sensor; and (b) a respective ambient shearing current profile, wherein the respective ambient shearing current profile is based on ambient current values and directions at different locations within the body of the fluid, related to the respective distinct location;
based on the wave measurements and the ambient shearing currents profile, assessing wave directional spectra characterizing flow regime of waves of the body of fluid, while accounting for the effects of the ambient shearing currents during the wave measurements' period of time; and
determining, based on the assessed wave directional spectra, one or more design parameters of the maritime infrastructure.
